(19) United States
(12) Patent Application Publication
(10) Pub. No.: US 2016/0064297 A1
(43) Pub. Date: Mar. 3, 2016

(54) UNDER-FILL MATERIAL, SEALING SHEET, AND METHOD FOR PRODUCING SEMICONDUCTOR DEVICE

(71) Applicant: NITTO DENKO CORPORATION, Osaka (JP)

(72) Inventors: Kosuke Morita, Ibaraki-shi (JP); Naohide Takamoto, Ibaraki-shi (JP)

(21) Appl. No.: 14/779,839

(22) PCT Filed: Mar. 19, 2014
(86) PCT No.: PCT/JP2014/057535

§ 371 Date: Sep. 24, 2015

(30) Foreign Application Priority Data
Mar. 26, 2013 (JP) 2013-064589

(51) Int. Cl. H01L 23/29; B32B 7/12; H01L 23/00; H01L 21/56; H01L 21/683

(52) U.S. Cl. CPC H01L 23/29; H01L 21/563; H01L 21/6836; H01L 24/81; B32B 7/12; H01L 2221/68327; H01L 2224/81191; B32B 2457/14; B32B 2307/51

(57) ABSTRACT

Provided are an under-fill material which is capable of reducing a difference in thermal response behavior between a semiconductor element and an adherend and which makes it easy and convenient to perform alignment for mounting the semiconductor element, a sealing sheet including the under-fill material, and a method for producing a semiconductor device using the under-fill material. In the under-fill material of the present invention, a haze is 70% or less before a heat curing treatment, and a storage elastic modulus E′ [MPa] and a thermal expansion coefficient α [ppm/K] after the under-fill material is subjected to a heat curing treatment at 175° C. for 1 hour satisfy the following formula (1) at 25° C.: 10000<E′×α<250000 [Pa/K].

### TECHNICAL FIELD

The present invention relates to an under-fill material, a sealing sheet, and a method for producing a semiconductor device.

### BACKGROUND ART

In recent years, demands for high-density mounting have been increased as electronic instruments have become smaller and thinner. Accordingly, for semiconductor packages, the surface mount type suitable for high-density mounting has become mainstream, in place of the conventional pin insertion type. In the surface mount type, a lead is soldered directly to a printed board or the like. For a heating method, the whole of a package is heated by infrared reflow, vapor phase reflow, solder dip, or the like to perform mounting.

After surface mounting, a sealing resin is filled in a space between a semiconductor element and a substrate for ensuring protection of the surface of the semiconductor element and connection reliability between the semiconductor element and the substrate. As this sealing resin, a liquid sealing resin is widely used, but it is difficult to adjust an injection position and an injection amount with the liquid sealing resin. Thus, there has been proposed a technique of filling a space between a semiconductor element and a substrate using a sheet-like sealing resin (Patent Document 1).

Generally, for a process using a sheet-like sealing resin (an under-fill material), such a procedure is employed that an under-fill material is attached to a semiconductor wafer, the semiconductor wafer is then diced to form a semiconductor element, and a space between an adherend such as a substrate and the semiconductor element is filled with the under-fill material integrated with the semiconductor element while connecting the semiconductor element to the adherend to perform mounting. In this process, a space between an adherend and a semiconductor element is easily filled.

### PRIOR ART DOCUMENT

### Patent Document

Patent Document 1: Japanese Patent No. 4438973

### DISCLOSURE OF THE INVENTION

### Problems to be Solved by the Invention

The semiconductor device may be made smaller and thinner by reducing the thickness of the semiconductor element, but influences of the thermal-responsive behavior of the adherend (warp and expansion, etc.) on the semiconductor element increase as the semiconductor element becomes thinner. This results from the fact that the thermal expansion coefficient of an adherend such as a substrate is generally higher than that of a semiconductor element. Particularly, stress resulting from a difference in thermal-responsive behavior between the semiconductor element and the adherend tends to localize on a connection member such as a solder bump for connecting the semiconductor element and the adherend, and the joint may be broken in some cases. As a measure against this, the materials and the like of the semiconductor element and the adherend can be selected so as to match the thermal-responsive behaviors of the former and the latter, but a range of materials that can be selected is limited.

On the other hand, the circuit width and the distance between terminals in a semiconductor element have decreased, and accordingly occurrence of even slight shifting at the time of matching to a connection position during mounting may cause damage of the semiconductor element, a failure of bonding during mounting, or the like, leading to a reduction in yield ratio in production of semiconductor devices.

Regarding registration during mounting, a sheet-shaped under-fill material is laminated on a semiconductor element beforehand, and therefore the under-fill material is required to have transparency which ensures that an alignment mark provided on the semiconductor element can be recognized at the time of alignment of the semiconductor element and the substrate during mounting of the semiconductor element. However, when a silica filler or the like is added to the under-fill material for reducing a difference in thermal expansion coefficient between the semiconductor element and the adherend, the transparency of the under-fill material is reduced, so that it maybe difficult to perform alignment of the semiconductor element and the substrate during mounting of the semiconductor element.

An object of the present invention is to provide an under-fill material which is capable of reducing a difference in thermal response behavior between a semiconductor element and an adherend and which makes it easy and convenient to perform alignment for mounting the semiconductor element, a sealing sheet including the under-fill material, and a method for producing a semiconductor device using the under-fill material.

### Means for Solving the Problems

The inventors of the present application have extensively conducted studies, and resultantly found that by employing the configuration described below, the above-mentioned object can be achieved, leading to completion of the present invention.

In an under-fill material according to the present invention, the haze is 70% or less before a heat curing treatment, and the storage elastic modulus E′ [MPa] and the thermal expansion coefficient α [ppm/K] after the under-fill material is subjected to a heat curing treatment at 175° C. for 1 hour satisfy the following formula (1) at 25° C.:

10000<E′×α<250000 [Pa/K] (1).

Since the storage elastic modulus E′ [MPa] and the thermal expansion coefficient α [ppm/K] of the under-fill material after heat curing satisfy the formula (1), a difference in thermal-responsive behavior between a semiconductor element and an adherend can be reduced, so that a semiconductor device, whose joint is inhibited from being broken and thereby has a high connection reliability, can be obtained. In the formula (1), the storage elastic modulus E′ and the thermal expansion coefficient α are inversely proportional to each other. As the storage elastic modulus E′ increases, the stiffness of the under-fill material itself is improved, so that stress can be absorbed or scattered. At this time, the thermal expansion coefficient α decreases, and the thermal expansion behavior of the under-fill material itself is suppressed, so that mechanical damages to adjacent members (i.e., semiconductor element and adherend) can be reduced. On the other hand, as the storage elastic modulus E′ decreases, the plasticity of the under-fill material itself is improved, so that the thermal-responsive behavior of the adjacent members, especially the adherend can be absorbed. At this time, the thermal expansion coefficient α increases, and the thermal-responsive behavior of the under-fill material conforms to the thermal-responsive behavior of the adherend, while influences on the semiconductor element is suppressed due to a decrease in the storage elastic modulus E′, so that stress as a whole is relaxed. As seen from the above, since optimum relaxation of mutual stress of the semiconductor element, the adherend, and the under-fill material can be achieved, breakage of a connection member can also be suppressed, and resultantly the connection reliability of the semiconductor device can be improved. Moreover, position matching can be accurately and easily performed during mounting of the semiconductor element because the haze before the heat curing treatment is controlled to 70% or less. Thus, with the under-fill material, reduction of the thermal response behavior between the semiconductor element and the adherend and facilitation of position matching during mounting of the semiconductor element can be efficiently balanced. Methods for measurement of the storage elastic modulus E′, the thermal expansion coefficient α , and the haze are as described in examples.

Preferably, the under-fill material has a range of not more than 20,000 Pa·s as a viscosity at 40 to 100° C., and has a minimum viscosity of 100 Pa·s or more at 100 to 200° C. Since the under-fill material has a range of not more than 20,000 Pa·s as a viscosity at to 100° C., embeddability of the under-fill material in irregularities of the semiconductor element during bonding is satisfactory, so that generation of voids between the under-fill material and the semiconductor element can be prevented. Since the minimum viscosity of the under-fill material at 100 to 200° C. is 100 Pa·s or more, generation of voids due to drift of the under-fill material during bonding can be prevented, and also generation of voids resulting from moisture absorption and outgas can be prevented, so that high reliability can be achieved.

The present invention also includes a sealing sheet which includes a pressure-sensitive adhesive tape including a base material and a pressure-sensitive adhesive layer provided on the base material; and the under-fill material laminated on the pressure-sensitive adhesive layer.

By integrally using the under-fill material and the pressure-sensitive adhesive tape, the efficiency of a production process ranging from processing of a semiconductor wafer to mounting of a semiconductor element can be enhanced.

In the sealing sheet, a peel strength of the under-fill material from the pressure-sensitive adhesive tape is preferably 0.03 to 0.10 N/20 mm. Accordingly, rupture and deformation of the under-fill material at the time of peeling off the under-fill material from the pressure-sensitive adhesive tape can be prevented, and for example, when the pressure-sensitive adhesive tape is a dicing tape, pickup of the semiconductor wafer after dicing can be easily performed.

In the sealing sheet, a rupture elongation of the under-fill material at 25° C. is preferably not less than 10% and not more than 800%. Accordingly, rupture does not occur even when expansion/contraction action is applied before bonding to the semiconductor element, and in addition, rupture of the under-fill material itself can be prevented even when the peel strength is applied at the time of peeling off the under-fill material. Thus satisfactory handling characteristics can be achieved.

The pressure-sensitive adhesive tape may be a backside grinding tape for a semiconductor wafer, or may be a dicing tape for a semiconductor wafer.

The present invention also includes a method for producing a semiconductor device which includes an adherend, a semiconductor element electrically connected to the adherend, and an under-fill material filling a space between the adherend and the semiconductor element, the method including the steps of:

providing a semiconductor element with an under-fill material in which the under-fill material is bonded to the semiconductor element; and

electrically connecting the semiconductor element and the adherend to each other while filling the space between the adherend and the semiconductor element with the under-fill material.

In the production method, a predetermined under-fill material is used, and therefore an alignment mark provided on the semiconductor element or the adherend can be precisely recognized. Accordingly, position matching can be correctly and easily and conveniently performed at the time of mounting the semiconductor element on the adherend, and a semiconductor device can be produced with a satisfactory yield ratio without causing an error in electrical connection. Further, a difference in thermal expansion coefficient between the semiconductor element and the adherend can be reduced, so that a semiconductor device having high connection reliability can be produced.

### BRIEF DESCRIPTION OF THE DRAWINGS

FIG. 1 is a sectional schematic view showing a sealing sheet according to one embodiment of the present invention.

FIG. 2A is a sectional schematic view showing one step of a process for production of a semiconductor device according to one embodiment of the present invention.

FIG. 2B is a sectional schematic view showing one step of the process for production of a semiconductor device according to one embodiment of the present invention.

FIG. 2C is a sectional schematic view showing one step of the process for production of a semiconductor device according to one embodiment of the present invention.

FIG. 2D is a sectional schematic view showing one step of the process for production of a semiconductor device according to one embodiment of the present invention.

FIG. 2E is a sectional schematic view showing one step of the process for production of a semiconductor device according to one embodiment of the present invention.

FIG. 2F is a sectional schematic view showing one step of the process for production of a semiconductor device according to one embodiment of the present invention.

FIG. 2G is a sectional schematic view showing one step of the process for production of a semiconductor device according to one embodiment of the present invention.

FIG. 2H is a sectional schematic view showing one step of the process for production of a semiconductor device according to one embodiment of the present invention.

FIG. 3A is a sectional schematic view showing one step of a process for production of a semiconductor device according to another embodiment of the present invention.

FIG. 3B is a sectional schematic view showing one step of the process for production of a semiconductor device according to another embodiment of the present invention.

FIG. 3C is a sectional schematic view showing one step of the process for production of a semiconductor device according to another embodiment of the present invention.

FIG. 3D is a sectional schematic view showing one step of the process for production of a semiconductor device according to another embodiment of the present invention.

FIG. 3E is a sectional schematic view showing one step of the process for production of a semiconductor device according to another embodiment of the present invention.

### MODE FOR CARRYING OUT THE INVENTION

### First Embodiment

Hereinafter, one embodiment of the present invention will be described using as an example a sealing sheet with an under-fill material integrated with a backside grinding tape, and a method for producing a semiconductor device using the sealing sheet. Therefore, in this embodiment, a backside grinding tape is used as a pressure-sensitive adhesive tape. Basically, the descriptions below can also be applied to the under-fill material alone.

In this embodiment, backside grinding of a semiconductor wafer is performed using a sealing tape including an under-fill material laminated on a backside grinding tape, followed by performing dicing on a dicing tape and pickup of a semiconductor element, and finally mounting the semiconductor element on an adherend.

Typical steps in this embodiment include a providing step of providing a sealing sheet including a backside grinding tape and an under-fill material laminated on the backside grinding tape; a bonding step of bonding a circuit surface provided with a connection member for a semiconductor wafer and the under-fill material of the sealing sheet; a grinding step of grinding the back surface of the semiconductor wafer; a fixing step of peeling off the semiconductor wafer from the backside grinding tape along with the under-fill material, and bonding the semiconductor wafer to a dicing tape; a dicing position determining step of determining a dicing position on the semiconductor wafer; a dicing step of dicing the semiconductor wafer to form a semiconductor element with the under-fill material; a pickup step of peeling off the semiconductor element with the under-fill material from the dicing tape; a position matching step of matching the relative positions of the semiconductor element and the adherend to a position at which the semiconductor element and the adherend are to be connected to each other; and a connection step of electrically connecting the semiconductor element and the adherend to each other through the connection member while filling a space between the adherend and the semiconductor element with the under-fill material.

[Providing Step]

In the providing step, a sealing sheet including a backside grinding tape and an under-fill material laminated on the backside grinding tape is provided.

(Sealing Sheet)

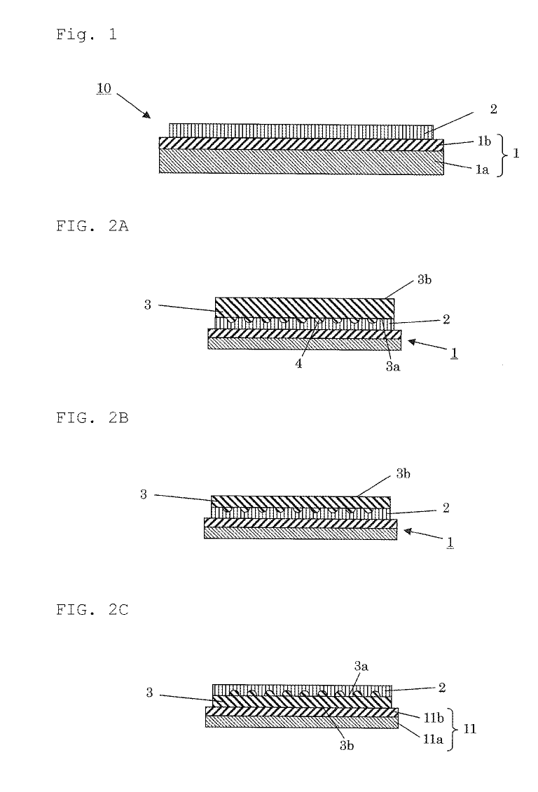

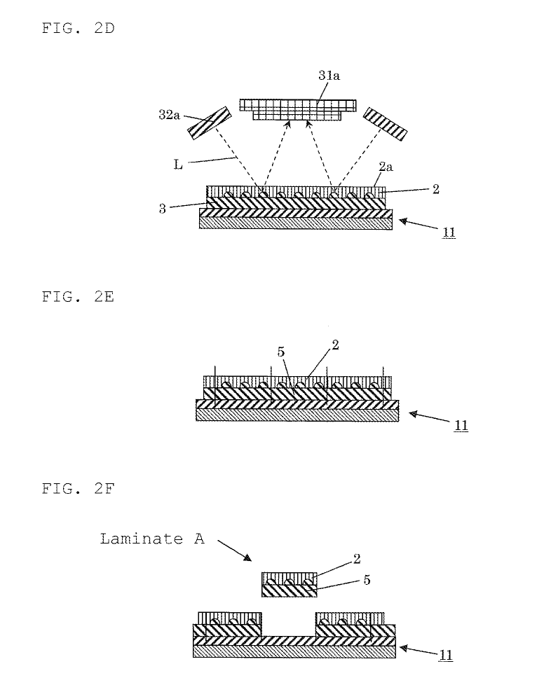

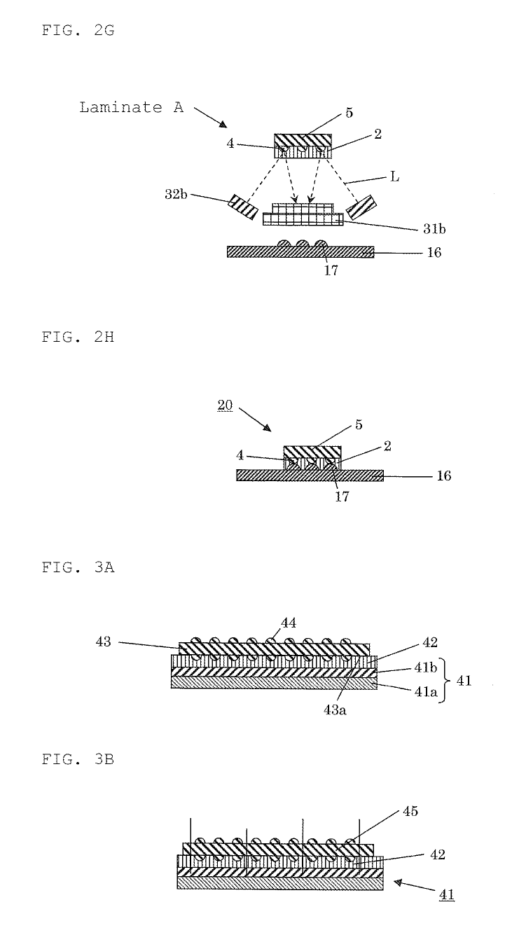

As shown in FIG. 1, a sealing sheet 10 has a backside grinding tape 1 and an under-fill material 2 laminated on the backside grinding tape 1. As shown in FIG. 1, the under-fill material 2 maybe provided in a size sufficient for bonding with a semiconductor wafer 3 (see FIG. 2A), or may be laminated on the entire surface of the backside grinding tape 1.

(Backside Grinding Tape)

The backside grinding tape 1 includes a base material 1a, and a pressure-sensitive adhesive layer 1b laminated on the base material 1a. The under-fill material 2 is laminated on the pressure-sensitive adhesive layer 1b.

(Base Material)

The base material 1a is a reinforcement matrix for the sealing sheet 10. Examples include polyolefins such as low-density polyethylene, linear polyethylene, medium-density polyethylene, high-density polyethylene, very low-density polyethylene, random copolymerized polypropylene, block copolymerized polypropylene, homo polypropylene, polybutene, and polymethylpentene, an ethylene-vinyl acetate copolymer, an ionomer resin, an ethylene-(meth)acrylic acid copolymer, an ethylene-(meth)acrylate (random, alternating) copolymer, an ethylene-butene copolymer, an ethylene-hexene copolymer, polyurethane, polyesters such as polyethylene terephthalate and polyethylene naphthalate, polycarbonate, polyimide, polyether ether ketone, polyimide, polyetherimide, polyamide, total aromatic polyamide, polyphenyl sulfide, alamid (paper), glass, glass cloth, a fluororesin, polyvinyl chloride, polyvinylidene chloride, a cellulose-based resin, a silicone resin, a metal (foil), and papers such as glassine paper. When the pressure-sensitive adhesive layer 1b is of an ultraviolet-ray curing type, the base material 1a is preferably one having a permeability to ultraviolet rays.

In addition, examples of the material of the base material 1a include polymers such as cross-linked products of the resins described above. For the plastic film described above, an unstretched film may be used, or a film subjected to uniaxial or biaxial stretching may be used as necessary.

The surface of the base material 1a can be subjected to a common surface treatment, for example, a chemical or physical treatment such as a chromic acid treatment, ozone exposure, flame exposure, high-voltage electrical shock exposure or an ionized radiation treatment, or a coating treatment with a primer (e.g. adhesive substance to be described) for improving adhesion with an adjacent layer, the retention property, and so on.

For the base material 1a, the same material or different materials can be appropriately selected and used, and one obtained by blending several materials can be used as necessary. The base material 1a can be provided thereon with a vapor-deposited layer of an electrically conductive substance made of a metal, an alloy, an oxide thereof, or the like and having a thickness of about 30 to 500 A for imparting an antistatic property. The antistatic property can also be provided by adding an antistatic agent into the base material. The base material 1a may be a single layer or a multiple layer having two or more layers.

The thickness of the base material 1a is not particularly limited, and can be appropriately determined, but is generally about 5 to 200 μm, and is preferably 35 to 120 μm.

The base material 1a may contain various kinds of additives (e.g. colorant, filler, plasticizer, antiaging agent, antioxidant, surfactant, flame retardant, etc.) within the bounds of not impairing the effect of the present invention.

(Pressure-Sensitive Adhesive Layer)

A pressure-sensitive adhesive to be used for formation of the pressure-sensitive adhesive layer 1b is not particularly limited as long as the semiconductor wafer can be firmly retained with the interposition of the under-fill material in backside grinding, and the semiconductor wafer with the under-fill material can be peelably controlled in transference of the semiconductor wafer with the under-fill material to the dicing tape after backside grinding. For example, a general pressure-sensitive adhesive such as an acryl-based pressure-sensitive adhesive or a rubber-based pressure-sensitive adhesive can be used. As the pressure-sensitive adhesive, an acryl-based pressure-sensitive adhesive having an acryl-based polymer as a base polymer is preferable from the viewpoint of ease of cleaning of an electronic component sensitive to contamination, such as a semiconductor wafer or glass, using ultrapure water or an organic solvent such as an alcohol.

Examples of the acryl-based polymer include those using an acrylate as a main monomer component. Examples of the acrylate include one or more of (meth)acrylic acid alkyl esters (for example, linear or branched alkyl esters with the alkyl group having 1 to 30, particularly 4 to 18 carbon atoms, such as methyl ester, ethyl ester, propyl ester, isopropyl ester, butyl ester, isobutyl ester, s-butyl ester, t-butyl ester, pentyl ester, isopentyl ester, hexyl ester, heptyl ester, octyl ester, 2-ethylhexyl ester, isooctyl ester, nonyl ester, decyl ester, isodecyl ester, undecyl ester, dodecyl ester, tridecyl ester, tetradecyl ester, hexadecyl ester, octadecyl ester and eicosyl ester), and (meth)acrylic acid cycloalkyl esters (for example, cyclopentyl ester and cyclohexyl ester, etc.). The (meth)acrylic acid ester refers to an acrylic acid ester and/or a methacrylic acid ester, and (meth) has the same meaning throughout the present invention.

The acryl-based polymer may contain a unit corresponding to any other monomer component capable of being copolymerized with the (meth)acrylic acid alkyl ester or cycloalkyl ester as necessary for the purpose of modifying cohesive strength, heat resistance and so on. Examples of the monomer component include carboxyl group-containing monomers such as acrylic acid, methacrylic acid, carboxyethyl(meth)acrylate, carboxypentyl(meth)acrylate, itaconic acid, maleic acid, fumaric acid and crotonic acid; acid anhydride monomers such as maleic anhydride and itaconic anhydride; hydroxyl group-containing monomers such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate and (4-hydroxymethylcyclohexyl)-methyl(meth)acrylate; sulfonic acid group-containing monomers such as styrenesulfonic acid, allylsulfonic acid, 2-(meth)acrylamide-2-methylpropanesulfonic acid, (meth)acrylamidepropanesulfonic acid, sulfopropyl(meth)acrylate, and (meth)acryloyloxynaphthalenesulfonic acid; phosphoric acid group-containing monomers such as 2-hydroxyethylacryloyl phosphate; and acrylamide and acrylonitrile. One or more of these monomers capable of being copolymerized can be used. The used amount of the monomer component capable of copolymerization is preferably 40% by weight or less based on total monomer components.

Further, the acryl-based polymer may contain a polyfunctional monomer or the like as a monomer component for copolymerization as necessary for the purpose of cross-linking. Examples of the polyfunctional monomer include hexanediol di(meth)acrylate, (poly)ethylene glycol di(meth)acrylate, (poly)propylene glycol di(meth)acrylate, neopentylglycol di(meth)acrylate, pentaerythrithol di(meth)acrylate, trimethylolpropane tri(meth)acrylate, pentaerythrithol tri(meth)acrylate, dipentaerythrithol hexa(meth)acrylate, epoxy(meth)acrylate, polyester(meth)acrylate, and urethane(meth)acrylate. One or more of these polyfunctional monomers can be used. The used amount of the polyfunctional monomer is preferably 30% by weight or less based on total monomer components from the viewpoint of an adhesion property.

The acryl-based polymer is obtained by subjecting a single monomer or monomer mixture of two or more kinds of monomers to polymerization. Polymerization can be carried out by any method such as solution polymerization, emulsion polymerization, bulk polymerization, or suspension polymerization. The content of low-molecular weight substances is preferably low from the viewpoint of prevention of contamination of a clean adherend. In this respect, the number average molecular weight of the acryl-based polymer is preferably 300,000 or more, further preferably about 400,000 to 3,000,000.

For the pressure-sensitive adhesive, an external cross-linker can also be appropriately employed for increasing the number average molecular weight of an acryl-based polymer or the like as a base polymer. Specific examples of the external cross-linking methods include a method in which a so-called cross-linker such as a polyisocyanate compound, an epoxy compound, an aziridine compound, or a melamine-based cross-linker is added and reacted. When an external cross-linker is used, the used amount thereof is appropriately determined according to a balance with a base polymer to be cross-linked, and further a use application as a pressure-sensitive adhesive. Generally, the external cross-linker is blended in an amount of preferably about 5 parts by weight or less, further preferably 0.1 to 5 parts by weight, based on 100 parts by weight of the base polymer. Further, for the pressure-sensitive adhesive, various previously known kinds of additives, such as a tackifier and an anti-aging agent, maybe used as necessary in addition to the aforementioned components.

The pressure-sensitive adhesive layer 1b can be formed by radiation curing-type pressure-sensitive adhesive. By irradiating the radiation curing-type pressure-sensitive adhesive with radiations such as ultraviolet rays, the degree of cross-linking thereof can be increased to easily reduce its adhesive power, so that peeling of the semiconductor wafer with the under-fill material can be easily performed. Examples of radiations include X-rays, ultraviolet rays, electron rays, α rays, β rays, and neutron rays.

For the radiation curing-type pressure-sensitive adhesive, one having a radiation-curable functional group such as a carbon-carbon double bond and showing adherability can be used without particular limitation. Examples of the radiation curing-type pressure-sensitive adhesive may include, for example, an addition-type radiation-curable pressure-sensitive adhesive obtained by blending a radiation-curable monomer component or an oligomer component with a general pressure-sensitive adhesive such as the above-mentioned acryl-based pressure-sensitive adhesive or rubber-based pressure-sensitive adhesive.

Examples of the radiation curable monomer component to be blended include urethane oligomer, urethane(meth)acrylate, trimethylolpropane tri(meth)acrylate, tetramethylolmethane tetra(meth)acrylate, pentaerythrithol tri(meth)acrylate, pentaerythrithol tetra(meth)acrylate, dipentaerythrithol monohydroxypenta(meth)acrylate, dipentaerythrithol hexa(meth)acrylate, and 1,4-butanediol di(meth)acrylate. Examples of the radiation curable oligomer component include various oligomers such as urethane-based, polyether-based, polyester-based, polycarbonate-based and polybutadiene-based oligomers, and the appropriate weight-average molecular weight thereof is in a range of about 100 to 30,000. For the blending amount of the radiation curable monomer component or oligomer component, an amount allowing the adhesive strength of the pressure-sensitive adhesive layer to be reduced can be appropriately determined according to the type of the pressure-sensitive adhesive layer. Generally, the blending amount is, for example, 5 to 500 parts by weight, preferably about 40 to 150 parts by weight, based on 100 parts by weight of a base polymer such as an acryl-based polymer forming the pressure-sensitive adhesive.

Examples of the radiation curing-type pressure-sensitive adhesive include, besides the addition-type radiation curing-type pressure-sensitive adhesive described previously, an intrinsic radiation curing-type pressure-sensitive adhesive using, as a base polymer, a polymer having a carbon-carbon double bond in the polymer side chain or main chain or at the end of the main chain. The intrinsic radiation curing-type pressure-sensitive adhesive is preferable because it is not required to contain, or mostly does not contain, an oligomer component or the like which is a low-molecular component, and therefore the oligomer component or the like does not migrate in the pressure-sensitive adhesive over time, so that a pressure-sensitive adhesive layer having a stable layer structure can be formed.

For the base polymer having a carbon-carbon double bond, one having a carbon-carbon double bond and also an adherability can be used without any particular limitation. Such a base polymer is preferably one having an acryl-based polymer as a basic backbone. Examples of the basic backbone of the acryl-based polymer include the acryl-based polymers described previously as an example.

The method for introducing a carbon-carbon double bond into the acryl-based polymer is not particularly limited, and various methods can be employed, but it is easy in molecular design to introduce the carbon-carbon double bond into a polymer side chain. Mention is made to, for example, a method in which a monomer having a functional group is copolymerized into an acryl-based polymer beforehand, and thereafter a compound having a functional group that can react with the above-mentioned functional group, and a carbon-carbon double bond is subjected to a condensation or addition reaction while maintaining the radiation curability of the carbon-carbon double bond.

Examples of the combination of these functional groups include a combination of a carboxylic acid group and an epoxy group, a combination of a carboxylic acid group and an aziridyl group, and a combination of a hydroxyl group and an isocyanate group. Among these combinations of functional groups, the combination of a hydroxyl group and an isocyanate group is suitable in terms of ease of reaction tracing. The functional group may be present at the side of any of the acryl-based polymer and the aforementioned compound as long as the combination of the functional groups is such a combination that the acryl-based polymer having a carbon-carbon double bond is generated, but for the preferable combination, it is preferred that the acryl-based polymer have a hydroxyl group and the aforementioned compound have an isocyanate group. In this case, examples of the isocyanate compound having a carbon-carbon double bond include metacryloyl isocyanate, 2-metacryloyloxyethyl isocyanate, m-isopropenyl-α,α-dimethylbenzyl isocyanate. As the acryl-based polymer, one obtained by copolymerizing the hydroxy group-containing monomers described previously as an example, ether-based compounds such as 2-hydroxyethylvinyl ether, 4-hydroxybutyl vinyl ether and diethylene glycol monovinyl ether, and so on is used.

For the intrinsic radiation curing-type pressure-sensitive adhesive, the base polymer (particularly acryl-based polymer) having a carbon-carbon double bond can be used alone, but the radiation curable monomer component or oligomer component within the bounds of not deteriorating properties can also be blended. The amount of the radiation curable oligomer component or the like is normally within a range of 30 parts by weight or less, preferably in a range of 0 to 10 parts by weight, based on 100 parts by weight of the base polymer.

A photopolymerization initiator is preferably included in the radiation curing-type pressure-sensitive adhesive when it is cured by ultraviolet rays or the like. Examples of the photopolymerization initiator include α-ketol-based compounds such as 4-(2-hydroxyethoxy)phenyl(2-hydroxy-2-propyl)ketone, α-hydroxy-α,α′-dimethylacetophenone, 2-methyl-2-hydroxypropiophenone, and 1-hydroxycyclohexyl phenyl ketone; acetophenone-based compounds such as methoxyacetophenone, 2,2-dimethoxy-2-phenylacetophenone, 2,2-diethoxyacetophenone, and 2-methyl-1-[4-(methylthio)-phenyl]-2-morphorinopropane-1; benzoin ether-based compounds such as benzoin ethyl ether, benzoin isopropyl ether, and anisoin methyl ether; ketal-based compounds such as benzyldimethylketal; aromatic sulfonyl chloride-based compounds such as 2-naphthalenesulfonyl chloride; photoactive oxime-based compounds such as 1-phenyl-1,2-propanedione-2-(O-ethoxycarbonyl)oxime; benzophenone-based compounds such as benzophenone, benzoyl benzoic acid, and 3,3′-dimethyl-4-methoxybenzophenone; thioxanthone-based compounds such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketone; acylphosphinoxide; and acylphosphonate. The blending amount of the photopolymerization initiator is, for example, about 0.05 to 20 parts by weight based on 100 parts by weight of the base polymer such as an acryl-based polymer which forms a pressure-sensitive adhesive.

When curing hindrance by oxygen occurs at the time of the irradiation of radiations, it is desirable to block oxygen (air) from the surface of the radiation curing-type pressure-sensitive adhesive layer 1b by some method. Examples include a method in which the surface of the pressure-sensitive adhesive layer 1b is covered with a separator, and a method in which irradiation of radiations such as ultraviolet rays or the like is carried out in a nitrogen gas atmosphere.

The pressure-sensitive adhesive layer 1b may contain various kinds of additives (e.g. colorant, thickener, bulking agent, filler, tackifier, plasticizer, antiaging agent, antioxidant, surfactant, cross-linker, etc.).

The thickness of the pressure-sensitive adhesive layer 1b is not particularly limited, but is preferably about 1 to 50 μm from the viewpoint of prevention of chipping of a ground surface of the semiconductor wafer, compatibility of fixation and retention of an under-fill material 2, and so on. The thickness is preferably 5 to more preferably 10 to 30 μm.

(Under-Fill Material)

The under-fill material 2 in this embodiment can be used as a sealing film that fills a space between a surface mounted (e.g. flip-chip-mounted) semiconductor element and an adherend. The upper limit of the haze before the under-fill material 2 is subjected to a heat curing treatment should be 70% or less, and is preferably 50% or less, more preferably 30% or less. The lower limit of the haze of the under-fill material 2 is preferably as low as possible (e.g. 0%), but may be 1% or more in view of physical limitations. Accordingly, the position of the semiconductor element can be accurately detected in determination of a dicing position for dicing and matching to a connection position for mounting.

In the under-fill material of this embodiment, a storage elastic modulus E′ [MPa] and a thermal expansion coefficient α [ppm/K] after carrying out a heat-curing treatment at 175° C. for an hour satisfy the following formula (1) at 25° C.

10,000<E′×α<250,000 [Pa/K] (1)

Owing to this under-fill material, a difference in thermal-responsive behavior between the semiconductor element and the adherend can be reduced while securing visibility of an alignment mark, so that a semiconductor device, whose joint is inhibited from being broken and thereby having a high connection reliability, can be obtained. Since optimum relaxation of mutually acting stresses of the semiconductor element, the adherend, and the under-fill material can be achieved, breakage of the connection member can also be suppressed, and resultantly the connection reliability of the semiconductor device can be improved.

It is preferable that the storage elastic modulus E′ be 100 to 10,000 [MPa] and the thermal expansion coefficient α be 10 to 200 [ppm/K]. Stress on the whole system of the semiconductor device can be efficiently relaxed as the storage elastic modulus E′ and the thermal expansion coefficient α respectively falls in such range.

The glass transition temperature (Tg) of the under-fill material after heat curing treatment at 175° C. for an hour is preferably 100 to 180° C., more preferably 130 to 170° C. By ensuring that the glass transition temperature of the under-fill material after heat curing falls within the range, an abrupt change in properties within a temperature range in a heat cycle reliability test can be suppressed, so that a further improvement in reliability can be expected.

The rupture elongation of the under-fill material at 25° C. is preferably not less than 10% and not more than 800%, more preferably not less than 20% and not more than 500%, further preferably not less than 50% and not more than 200%. Accordingly, rupture does not occur even when expansion/contraction action is applied to the under-fill material before bonding to the semiconductor element, and in addition, rupture of the under-fill material itself can be prevented even when the peel strength is applied at the time of peeling off the under-fill material. Thus satisfactory handling characteristics can be achieved. The rupture elongation can be measured by a generally known measurement method using a tensile tester (Tensilon) or the like.

The material that forms the under-fill material is, for example, a combination of a thermoplastic resin and a thermosetting resin. Alternatively, a thermoplastic resin or a thermosetting resin alone can be used.

Examples of the thermoplastic resin include natural rubber, butyl rubber, isoprene rubber, chloroprene rubber, an ethylene-vinyl acetate copolymer, an ethylene-acrylic acid copolymer, an ethylene-acrylate copolymer, a polybutadiene resin, a polycarbonate resin, a thermoplastic polyimide resin, polyamide resins such as 6-nylon and 6,6-nylon, a phenoxy resin, an acrylic resin, saturated polyester resins such as PET and PBT, a polyamideimide resin, and a fluororesin. These thermoplastic resins can be used alone, or in combination of two or more thereof. Among these thermoplastic resins, an acrylic resin, which has less ionic impurities, has a high heat resistance, and can ensure the reliability of a semiconductor element, is especially preferable.

The acrylic resin is not particularly limited, and examples thereof include polymers having as a component one or more of esters of acrylic acids or methacrylic acids which have a linear or branched alkyl group having 30 or less of carbon atoms, especially 4 to 18 carbon atoms. Examples of the alkyl group include a methyl group, an ethyl group, a propyl group, an isopropyl group, an n-butyl group, a t-butyl group, an isobutyl group, an amyl group, an isoamyl group, a hexyl group, a heptyl group, a cyclohexyl group, a 2-ethylhexyl group, an octyl group, an isooctyl group, a nonyl group, an isononyl group, a decyl group, an isodecyl group, an undecyl group, a lauryl group, a tridecyl group, a tetradecyl group, a stearyl group, an octadecyl group, and an eicosyl group.

Other monomers for forming the polymer are not particularly limited, and examples thereof include carboxyl group-containing monomers such as acrylic acid, methacrylic acid, carboxyethyl acrylate, carboxypentylacrylate, itaconic acid, maleic acid, fumaric acid and crotonic acid, acid anhydride monomers such as maleic anhydride and itaconic anhydride, hydroxyl group-containing monomers such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxymethylcyclohexyl)-methyl acrylate, sulfonic acid group-containing monomers such as styrenesulfonic acid, allylsulfonic acid, 2-(meth)acrylamide-2-methylpropanesulfonic acid, (meth)acrylamidepropanesulfonic acid, sulfopropyl(meth)acrylate, and (meth)acryloyloxynaphthalenesulfonic acid, and phosphoric acid group-containing monomers such as 2-hydroxyethylacryloyl phosphate, and cyano group-containing momomers such as acrylonitrile.

Examples of the thermosetting resin include a phenol resin, an amino resin, an unsaturated polyester resin, an epoxy resin, a polyurethane resin, a silicone resin, and a thermosetting polyimide resin. These resins can be used alone, or in combination of two or more thereof. Particularly, an epoxy resin containing less ionic impurities that corrode a semiconductor element is preferable. A curing agent for the epoxy resin is preferably a phenol resin.

The epoxy resin is not particularly limited as long as it is generally used as an adhesive composition, and for example a difunctional epoxy resin or a polyfunctional epoxy resin such as a bisphenol A type, a bisphenol F type, a bisphenol S type, a brominated bisphenol A type, a hydrogenated bisphenol A type, a bisphenol AF type, a biphenyl type, a naphthalene type, a fluorene type, a phenol novolak type, an orthocresol novolak type, a trishydroxyphenyl methane type or a tetraphenylol ethane type, or an epoxy resin such as a hydantoin type, a trisglycidyl isocyanurate type, or a glycidyl amine type is used. They can be used alone, or in a combination of two or more thereof. Among these epoxy resins, a novolak type epoxy resin, a biphenyl type epoxy resin, a trishydroxyphenyl methane type resin, or a tetraphenylol ethane type epoxy resin is especially preferable. This is because the aforementioned resins have a high reactivity with a phenol resin as a curing agent, and are excellent in heat resistance, and so on.

Further, the phenol resin acts as a curing agent for the epoxy resin, and examples thereof include novolak type phenol resins such as a phenol novolak resin, a phenol aralkyl resin, a cresol novolak resin, a tert-butylphenol novolak resin, and a nonylphenol novolak resin, resole type phenol resins, and polyoxystyrenes such as polyparaoxystyrene. They can be used alone, or in combination of two or more thereof. Among these phenol resins, a phenol novolak resin and a phenol aralkyl resin are especially preferable. This is because the connection reliability of a semiconductor device can be improved.

For example, the epoxy resin and the phenol resin are preferably blended at such a blending ratio that the equivalent of the hydroxyl group in the phenol resin per one equivalent of the epoxy group in the epoxy resin component is 0.5 to 2.0 equivalents. More preferable is 0.8 to 1.2 equivalents. That is, if the blending ratio of the resins falls outside of the aforementioned range, the curing reaction does not proceed sufficiently, so that properties of the epoxy resin cured products are easily deteriorated.

In the present invention, an under-fill material using an epoxy resin, a phenol resin, and an acrylic resin is especially preferable. These resins have less ionic impurities and have high heat resistances, and therefore can ensure the reliability of a semiconductor element. The blending ratio in this case is such that the mixed amount of the epoxy resin and the phenol resin is 10 to 200 parts by weight based on 100 parts by weight of the acrylic resin component.

A heat curing accelerating catalyst for the epoxy resin and the phenol resin is not particularly limited, and can be appropriately selected from known heat curing accelerating catalysts and used. The heat curing accelerating catalyst can be used alone, or in a combination of two or more kinds. As the heat curing accelerating catalyst, for example, an amine-based curing accelerator, a phosphorus-based curing accelerator, an imidazole-based curing accelerator, a boron-based curing accelerator, or a phosphorus-boron-based curing accelerator can be used.

A flux maybe added to the under-fill material 2 for removing an oxide film on the surface of a solder bump to facilitate mounting of a semiconductor element. The flux is not particularly limited, a previously known compound having a flux action can be used, and examples thereof include diphenolic acid, adipic acid, acetylsalicylic acid, benzoic acid, benzilic acid, azelaic acid, benzylbenzoic acid, malonic acid, 2,2-bis(hydroxymethyl)propionic acid, salicylic acid, o-methoxybenzoic acid (o-anisic acid), m-hydroxybenzoic acid, succinic acid, 2,6-dimethoxymethyl paracresol, hydrazide benzoate, carbohydrazide, dihydrazide malonate, dihydrazide succinate, dihydrazide glutarate, hydrazide salicylate, dihydrazide iminodiacetate, dihydrazide itaconate, trihydrazide citrate, thiocarbohydrazide, benzophenone hydrazone, 4,4′-oxybisbenzenesulfonyl hydrazide, and dihydrazide adipate. The added amount of the flux may be such an amount that the flux action is exhibited, and is normally about 0.1 to 20 parts by weight based on 100 parts by weight of the resin component contained in the under-fill material.

In this embodiment, the under-fill material 2 maybe colored as long as the haze is 70% or less. In the under-fill material 2, the color shown by coloring is not particularly limited, but is preferably, for example, black, blue, red, or green. For coloring, a colorant can be appropriately selected from known colorants such as pigments and dyes and used.

When the under-fill material 2 of this embodiment is preliminarily cross-linked to a degree, a polyfunctional compound that reacts with a functional group or the like at the end of the molecular chain of a polymer should be added as a cross-linker at the time of preparation. Consequently, adhesion properties under a high temperature can be improved to improve the heat resistance.

As the cross-linker, particularly polyisocyanate compounds such as tolylene diisocyanate, diphenylmethane diisocyanate, p-phenylene diisocyanate, 1,5-naphthalene diisocyanate and an adduct of a polyhydric alcohol and a diisocyanate are more preferable. Preferably, the added amount of the cross-linker is normally 0.05 to 7 parts by weight based on 100 parts by weight of the polymer. If the amount of cross-linker is more than 7 parts by weight, the adhering strength is reduced, and thus is not preferable. On the other hand, if the amount of the cross-linker is less than 0.05 parts by weight, the cohesive strength becomes poor, and thus is not preferable. Other polyfunctional compounds such as an epoxy resin may be included as necessary together with the above-mentioned polyisocyanate compound.

An inorganic filler can be appropriately blended with the under-fill material 2. Blending of the inorganic filler allows impartment of electrical conductivity, improvement of thermal conductivity, adjustment of a storage elastic modulus, and so on.

Examples of the inorganic filler include various inorganic powders made of ceramics such as silica, clay, plaster, calcium carbonate, barium sulfate, aluminum oxide, beryllium oxide, silicon carbide, and silicon nitride; metals such as aluminum, copper, silver, gold, nickel, chromium, lead, tin, zinc, palladium, and solder, or alloys; and carbon. They can be used alone, or in combination of two or more thereof. Above all, silica, particularly fused silica is suitably used.

The average particle diameter of the inorganic filler is not particularly limited, but is preferably in a range of 0.005 to 10 μm, more preferably in a range of 0.01 to 5 μm, further preferably in a range of 0.05 to 2.0 μm. When the average particle size of the inorganic filler is less than 0.005 μm, particles are easily aggregated, so that it may be difficult to form the under-fill material. Further, the flexibility of the under-fill material may be reduced. On the other hand, when the average particle size is more than 10 μtm, inorganic particles are easily caught in a connection part between the under-fill material and the adherend, so that connection reliability of the semiconductor device may be deteriorated. Further, particles may be coarsened to increase the haze. The average particle diameter is a value determined by a photometric particle size analyzer (manufactured by HORIBA, Ltd.; Unit Name: LA-910).

The blending amount of the inorganic filler is preferably 10 to 400 parts by weight, more preferably 50 to 250 parts by weight, based on 100 parts by weight of the organic resin component. If the blending amount of the inorganic filler is less than 10 parts by weight, the storage elastic modulus may be reduced, thereby considerably deteriorating the stress reliability of a package. On the other hand, if the blending amount of the inorganic filler is more than 400 parts by weight, the haze may increase, or the fluidity of the under-fill material 2 may be deteriorated, so that the under-fill material may not sufficiently fill up raised and recessed portions of the substrate or semiconductor element, thus leading to generation of voids and cracks.

Besides the inorganic filler, other additives can be blended with the under-fill material 2 as necessary. Examples of other additives include a flame retardant, a silane coupling agent, and an ion trapping agent. Examples of the flame retardant include antimony trioxide, antimony pentaoxide, and a brominated epoxy resin. They can be used alone, or in combination of two or more thereof. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These compounds can be used alone, or in combination of two or more thereof. Examples of the ion trapping agent include a hydrotalcite and bismuth hydroxide. They can be used alone, or in combination of two or more thereof.

In this embodiment, the under-fill material before the heat curing treatment preferably has a range of not more than 20,000 Pa·s, more preferably not less than 100 Pa·s, and not more than 10,000 Pa·s as a viscosity at 40 to 100° C. When the under-fill material has a predetermined viscosity range in the above-mentioned temperature range, entry of the connection member 4 (see FIG. 2A) into the under-fill material 2 can be facilitated. Generation of voids in electrical connection of the semiconductor element 5 and protrusion of the under-fill material 2 from the space between the semiconductor element 5 and the adherend 16 can be prevented (see FIG. 2H).

The minimum viscosity of the under-fill material at 100 to 200° C. before the heat curing treatment is preferably 100 Pa·s or more, more preferably not less than 200 Pa·s and not more than 10,000 Pa·s, further preferably not less than 500 Pa·s and not more than 5,000 Pa·s. When the minimum viscosity of the under-fill material at 100 to 200° C. is 100 Pa·s or more, generation of voids due to drift of the under-fill material during bonding, and generation of voids due to outgas resulting from moisture absorption, etc., can be prevented.

The viscosity or minimum viscosity is a value measured by a parallel plate method using a rheometer (RS-1 manufactured by HAAKE Company). More specifically, the melt viscosity is measured over a range of 40° C. to 200° C. under the conditions of a gap of 100 μm, a rotation cone diameter of 20 mm, a rotation speed of 5 s⁻¹, and a temperature rise rate of 10° C./minute, and whether or not the viscosity in a range of 40° C. to 100° C., which is obtained at this time, includes a range of not more than 20,000 Pa·s is determined. The minimum value of the viscosity in a range of 100° C. to 200° C. is defined as a minimum viscosity.

The viscosity of the under-fill material 2 at 23° C. before heat curing is preferably 0.01 M Pa·s to 100 M Pa·s inclusively, more preferably 0.1 M Pa·s to 10 M Pa·s inclusively. The under-fill material before heat curing has a viscosity in the above-mentioned range, whereby the retention property of a semiconductor wafer 3 (see FIG. 2B) at the time of backside grinding and the handling property at the time of operation can be improved.

Further, the water absorption rate of the under-fill material 2 at a temperature of 23° C. and a humidity of 70% before heat curing is preferably 1% by weight or less, more preferably 0.5% by weight or less. The under-fill material 2 has such a water absorption rate as described above, whereby absorption of moisture into the under-fill material 2 can be suppressed, so that generation of voids during mounting of the semiconductor element 5 can be more efficiently suppressed. The lower limit of the water absorption rate is preferably as low as possible, and is preferably substantially 0% by weight, more preferably 0% by weight.

The thickness of the under-fill material 2 (total thickness in the case of a multiple layer) is not particularly limited, but may be about 10 μm to 100 μm when considering the strength of the under-fill material 2 and performance of filling a space between the semiconductor element 5 and the adherend 16. The thickness of the under-fill material 2 may be appropriately set in consideration of the gap between the semiconductor element 5 and the adherend 16 and the height of the connection member.

The under-fill material 2 of the sealing sheet 10 is preferably protected by a separator (not shown). The separator has a function as a protective material for protecting the under-fill material 2 until actual use. The separator is peeled off when the semiconductor wafer 3 is attached onto the under-fill material 2 of the sealing sheet. As the separator, polyethylene terephthalate (PET), polyethylene, polypropylene, or a plastic film or paper of which a surface is coated with a release agent such as a fluorine-based release agent or a long-chain alkyl acrylate-based release agent can be used.

(Method for Producing a Sealing Sheet)

The sealing sheet 10 according to this embodiment can be prepared by, for example, preparing the back surface grinding tape and the under-fill material 2 separately in advance, and finally bonding the former and the latter together. Specifically, the sealing sheet 10 can be prepared in accordance with the following procedure.

First, the base material 1a can be film formed by a previously known film formation method. Examples of the method for a film formation may include a calendar film formation method, a casting method in an organic solvent, an inflation extrusion method in a closed system, a T-die extrusion method, a co-extrusion method, and a dry lamination method.

Next, a pressure-sensitive adhesive composition for formation of a pressure-sensitive adhesive layer is prepared. Resins and additives as described in the section relating to the pressure-sensitive adhesive layer, and so on are blended in the pressure-sensitive adhesive composition. The prepared pressure-sensitive adhesive composition is applied onto the base material 1a to form a coating film, and the coating film is then dried (cross-linked by heating as necessary) under predetermined conditions to form the pressure-sensitive adhesive layer 1b. The coating method is not particularly limited, and examples thereof include roll coating, screen coating and gravure coating. For drying conditions, for example, the drying temperature is in a range of 80 to 150° C., and the drying time is in a range of 0.5 to 5 minutes. The pressure-sensitive adhesive layer 1b may be formed by applying a pressure-sensitive adhesive composition onto a separator to form a coating film, followed by drying the coating film under the aforementioned conditions. Thereafter, the pressure-sensitive adhesive layer 1b is bonded onto the base material 1a together with the separator. In this way, the back surface grinding tape 1 including the base material 1a and the pressure-sensitive adhesive layer 1b is prepared.

For example, the under-fill material 2 is prepared in the following manner. First, an adhesive composition which is a material for forming the under-fill material 2 is prepared. A thermoplastic component, an epoxy resin, various kinds of additives, and so on are blended in the adhesive composition as described in the section relating to the under-fill material.

Next, the prepared adhesive composition is applied onto a base material separator in a predetermined thickness to form a coating film, followed by drying the coating film under predetermined conditions to form an under-fill material. The coating method is not particularly limited, and examples thereof include roll coating, screen coating, and gravure coating. For drying conditions, for example, the drying temperature is in a range of 70 to 160° C., and the drying time is in a range of 1 to 5 minutes. The under-fill material may be formed by applying a pressure-sensitive adhesive composition onto a separator to form a coating film, followed by drying the coating film under the aforementioned conditions. Thereafter, the under-fill material is bonded onto the base material separator together with the separator.

Subsequently, the separator is peeled off from each of the back surface grinding tape 1 and the under-fill material 2, and the tape and the under-fill material are bonded together such that the under-fill material and the pressure-sensitive adhesive layer form a bonding surface. Bonding can be performed by, for example, heat pressure-bonding. At this time, the lamination temperature is not particularly limited and is, for example, preferably 30 to 100° C., more preferably 40 to 80° C. The linear pressure is not particularly limited and is, for example, preferably 0.98 to 196 N/cm, more preferably 9.8 to 98 N/cm. Next, the base material separator on the under-fill material is peeled off to obtain a sealing sheet according to this embodiment.

[Bonding Step]

In the bonding step, a circuit surface 3a of the semiconductor wafer 3, on which the connection member 4 is formed, and the under-fill material 2 of the sealing sheet 10 are bonded(see FIG. 2A).

(Semiconductor Wafer)

A plurality of connection members 4 are formed on the circuit surface 3a of the semiconductor wafer 3 (see FIG. 2A). The material of the connection member such as a bump or an electrically conductive material is not particularly limited, and examples thereof include solders (alloys) such as a tin-lead-based metal material, a tin-silver-based metal material, a tin-silver-copper-based metal material, a tin-zinc-based metal material, a tin-zinc-bismuth-based metal material, a gold-based metal material, and a copper-based metal material. The height of the connection member is also determined according to an application, and is generally about 15 to 100 μm. Of course, the heights of individual connection members in the semiconductor wafer 3 may be the same or different.

In the method for producing a semiconductor device according to this embodiment, as the thickness of the under-fill material, the height X (μm) of the connection member formed on the surface of the semiconductor wafer and the thickness Y (μm) of the under-fill material preferably satisfies the following relationship:

0.5≦Y/X≦2

The height X (μm) of the connection member and the thickness Y (μm) of the cured film satisfy the above relationship, whereby a space between the semiconductor element and the adherend can be sufficiently filled, and excessive protrusion of the under-fill material from the space can be prevented, so that contamination of the semiconductor element by the under-fill material, and so on can be prevented. When the heights of the respective connection members are different, the height of the highest connection member is used as the reference.

(Bonding)

As shown in FIG. 2A, first a separator that is optionally provided on the under-fill 2 of the sealing sheet 10 is appropriately peeled off, the circuit surface 3a of the semiconductor wafer 3, on which the connection member 4 is formed, and the under-fill material 2 are made to face to each other, and the under-fill material 2 and the semiconductor wafer 3 are bonded together (mounting).

The method for bonding is not particularly limited, but is preferably a method by pressure-bonding. Pressure-bonding is normally performed by pressing with a pressure of preferably 0.1 to 1 MPa, more preferably 0.3 to 0.7 MPa by known pressing means such as a pressure roller. At this time, pressure-bonding may be carried out while heating to about 40 to 100° C. It is also preferable to carry out pressure-bonding under a reduced pressure (1 to 1,000 Pa) for improving adhesion.

[Grinding Step]

In the grinding step, a surface 3b opposite to the circuit surface 3a of the semiconductor wafer 3 (i.e., back surface) is ground (see FIG. 2B). A processor for thinning that is used for grinding the back surface of the semiconductor wafer 3 is not particularly limited, and examples thereof may include a grinding machine (back grinder) and a polishing pad. Back surface grinding may be carried out by a chemical process such as etching. Back surface grinding is carried out until the semiconductor wafer has a desired thickness (e.g. 50 to 500 μm).

[Fixation Step]

After the grinding step, the semiconductor wafer 3 with the under-fill material 2 bonded thereto is peeled off from the backside grinding tape 1, and the semiconductor wafer 3 and the dicing tape 11 are bonded together (see FIG. 2C). At this time, bonding is performed such that the back surface 3b of the semiconductor wafer 3 and a pressure-sensitive adhesive layer 11b of the dicing tape 11 are made to face to each other. Thus, the under-fill material 2 bonded to the circuit surface 3a of the semiconductor wafer 3 is exposed. The dicing tape 11 has such a structure that the pressure-sensitive adhesive layer 11b is laminated on a base material 11a. The base material 11a and the pressure-sensitive adhesive layer 11b can be suitably prepared using the components and the production method shown in the sections relating to the base material 1a and the pressure-sensitive adhesive layer 1b of the back surface grinding tape 1.

When the semiconductor wafer 3 is peeled off from the backside grinding tape 1, peeling can be facilitated by irradiating the pressure-sensitive adhesive layer 1b with radiations to cure the pressure-sensitive adhesive layer 1b in the case where the pressure-sensitive adhesive layer 1b has a radiation-curability. The amount of irradiation of radiations may be appropriately set in consideration of the type of radiations used and the degree of cure of the pressure-sensitive adhesive layer.

In the sealing sheet of this embodiment, the peel strength of the under-fill material from the backside grinding tape is preferably 0.03 to 0.10 N/20 mm. Due to such a low peel strength, rupture and deformation of the under-fill material at the time of peeling off the under-fill material from the backside grinding tape can be prevented, and deformation of the semiconductor wafer can be prevented.

For measurement of the peel strength, a sample piece having a width of 20 mm is cut out from a sealing sheet, and the sample piece is bonded to a silicon mirror wafer placed on a hot plate at 40° C. The sample piece is left standing for about 30 minutes, and the peel strength is measured using a tension tester. As measurement conditions, the peeling angle is 90°, and the tension rate is 300 mm/min. Measurement of the peel strength is performed under an environment at a temperature of 23° C. and a relative humidity of 50%. Note that when the pressure-sensitive adhesive layer is of the ultraviolet-ray curing-type, the sample piece is bonded to a silicon mirror wafer under the same conditions as described above, left standing for about 30 minutes, and then irradiated with an ultraviolet ray from the sealing sheet side under conditions for irradiation of the ultraviolet ray as described below, and the peel strength at this time is measured.

<Conditions for Irradiation of Ultraviolet Ray>

Ultraviolet ray (UV) irradiation device: high-pressure mercury lamp

Ultraviolet ray irradiation integrated light amount: 500 mJ/cm²

Power: 75 W

Irradiation intensity: 150 mW/cm²

[Dicing Position Determining Step]

Next, in the dicing position determining step, as shown in FIGS. 2D, the exposed surface 2a of the under-fill material 2 of the semiconductor wafer 3 with the under-fill material is irradiated with light L to determine a dicing position in the semiconductor wafer 3.

Specifically, an imaging device 31a and a ring illuminator (illuminator having a circular light emitting surface) 32a are placed above the semiconductor wafer 3 fixed to the dicing tape 11. Next, light L is irradiated from the ring illuminator 32a to the exposed surface 2a of the under-fill material 2. Light, which enters the under-fill material 2 and is reflected at the semiconductor wafer 3, is received as a reflected image in the imaging device 31a. The reflected image received is analyzed by an image recognition device to determine a position to be diced. Thereafter, a dicing device (e.g., dicing blade, laser generator, etc.) is moved and matched to the dicing position to complete this step (not shown).

As an illuminator for irradiation of light, a ring illuminator can be suitably used as described above, but the illuminator is not limited thereto, and a line illuminator (illuminator having a linear light emitting surface), a spot illuminator (illuminator having a spotted light emitting surface), or the like can be used. The illuminator may also be an illuminator with a plurality of line illuminators combined in a polygonal form, or an illuminator with spot illuminators combined in a polygonal or ring shape.

The light source of the illuminator is not particularly limited, and examples thereof include a halogen lamp, a LED, a fluorescent lamp, a tungsten lamp, a metal halide lamp, a xenon lamp, and a black light. Light L irradiated from the light source may be any of parallel light and radial light (non-parallel light), but parallel light is preferable when considering irradiation efficiency. However, there are physical limitations on irradiation of light L as parallel light, the light may be substantially parallel light (half-value angle: 30° or less). Light L may be polarized light.

The wavelength of the light is not particularly limited as long as a reflected image from the semiconductor wafer 3 is obtained, and the semiconductor wafer 3 is not damaged, but the wavelength of the light is preferably 300 to 900 nm, more preferably 400 to 800 nm. By ensuring that the wavelength of light falls within the above-mentioned range, a good permeability is shown even for an under-fill material formed of a general material including an inorganic filler, and therefore the dicing position can be more easily detected.

In FIG. 2D, an object to be recognized in the semiconductor wafer for detecting a position by irradiation of light is the connection member (e.g. bump) 4 formed on the semiconductor wafer 3, but is not limited thereto, and the object to be recognized may be an alignment mark, a terminal, a circuit pattern, or the like, or any mark or structure.

[Dicing Step]

In the dicing step, based on the dicing position determined in the dicing position determining step described above, the semiconductor wafer 3 and the under-fill material 2 are diced to form the semiconductor element 5 with the diced under-fill material as shown in FIG. 2E. Through the dicing step, the semiconductor wafer 3 is cut to a predetermined size and thereby formed into individual pieces (small pieces) to produce a semiconductor chip (semiconductor element) 5. The semiconductor chip 5 thus obtained is integrated with the under-fill material 2 cut in the same shape. Dicing is carried out from the circuit surface 3a of the semiconductor wafer 3, to which the under-fill material 2 is bonded, in accordance with a usual method.

In this step, for example, a cutting method called full cut, in which cutting with a dicing blade is made to the dicing tape 11, can be employed. The dicing device used in this step is not particularly limited, and one that is previously known can be used. The semiconductor wafer is adhesively fixed with excellent adhesion by the dicing tape 11, so that chipping and chip fly can be suppressed, and also damage of the semiconductor wafer can be suppressed. When the under-fill material is formed from a resin composition containing an epoxy resin, occurrence of protrusion of glue of the under-fill material at the cut surface can be suppressed or prevented even though the semiconductor wafer is cut by dicing. As a result, reattachment of cut surfaces (blocking) can be suppressed or prevented, so that pickup described later can be further satisfactorily performed.

When expanding of the sealing sheet is carried out subsequently to the dicing step, the expanding can be carried out using a previously known expanding device. The expanding device has a doughnut-like outer ring capable of depressing the sealing sheet via a dicing ring, and an inner ring having a diameter smaller than that of the outer ring and supporting the sealing sheet. Owing to the expanding step, adjacent semiconductor chips can be prevented from contacting with each other and damaged in a pickup step described later.

[Pickup Step]

As shown in FIG. 2F, pickup of the semiconductor chip 5 with the under-fill material 2 is carried out to peel off a laminate A of the semiconductor chip 5 and the under-fill material 2 from the dicing tape 11 for collecting the semiconductor chip 5 adhesively fixed on the dicing tape 11.

The method for pickup is not particularly limited, and various previously known methods can be employed. Mention is made of, for example, a method in which individual semiconductor chips are pushed up by a needle from the base material side of the laminated film, and the semiconductor chips, which have been pushed up, are collected by a pickup device. The semiconductor chip 5, which has been picked up, is integrated with the under-fill material 2 bonded to the circuit surface 3a to form the laminate A.

Here, pickup is performed after the pressure-sensitive adhesive layer 11b is irradiated with ultraviolet rays when the pressure-sensitive adhesive layer 11b is of an ultraviolet-ray curing type. Consequently, the tackiness of the pressure-sensitive adhesive layer 11b to the semiconductor chip 5 decreases, so that the semiconductor chip 5 can be easily peeled off. As a result, pickup can be performed without damaging the semiconductor chip 5. Conditions such as the irradiation intensity and the irradiation time at the time of irradiation of ultraviolet rays are not particularly limited, and may be appropriately set as necessary. As a light source used for irradiation of ultraviolet rays, for example, a low-pressure mercury lamp, a low-pressure high-power lamp, a medium-pressure mercury lamp, an electrodeless mercury lamp, a xenon flash lamp, an excimer lamp, an ultraviolet LED, or the like can be used.

[Position Matching Step]

Next, in the position matching step, as shown in FIGS. 2G, light L is irradiated to the exposed surface 2a of the under-fill material 2 of the semiconductor element 5 with the under-fill material, and relative positions of the semiconductor element 5 and the adherend 16 is matched to a predetermined position for connection of each other.

Specifically, a laminate A that is picked up is placed above the adherend 16 such that a surface of the semiconductor element 5, on which the connection member 4 is formed (corresponding to the circuit surface 3a of the semiconductor wafer 3) is made to face to the adherend 16. Then, the imaging device 31b and the ring illuminator 32b are placed between the laminate A and the adherend 16, followed by irradiating light L from the ring illuminator 32b toward the laminate A with respect to the exposed surface 2a of the under-fill material 2. Light, which enters the under-fill material 2 and is reflected at the semiconductor element 5, is received as a reflected image in the imaging device 31b. Next, the reflected image received is analyzed by an image recognition device, a displacement from a previously defined predetermined position for connection is determined, and finally a laminate A is moved by the determined displacement amount to match a relative position of the semiconductor element 5 and the adherend 16 to the predetermined position for connection (not shown).

The form of irradiation of light in this position matching step is different from that of irradiation of light in the dicing position determining step only in that the position of the exposed surface 2a of the under-fill material and the positions of the imaging device 31b and the illuminator 32b are vertically reversed. Thus, as conditions for irradiation of light, for example, an illuminator for irradiation of light, a light source of the illuminator, a wavelength of light, and an object to be recognized in the semiconductor element for position detection by irradiation of light, the conditions described in the section relating to the dicing position determining step can be suitably employed, and a comparable effect can be obtained.

[Mounting Process]

In the mounting process, the semiconductor element 5 and the adherend 16 are electrically connected through the connection member 4 while filling a space between the adherend 16 and the semiconductor element 5 using the under-fill material 2 (see FIG. 2H). Specifically, the semiconductor chip 5 of the laminate A is fixed to the adherend 16 in accordance with a normal method in such a form that the circuit surface 3a of the semiconductor chip 5 is made to face to the adherend 16. For example, the bump (connection member) 4 formed on the semiconductor chip 5 is contacted with an electrically conductive material 17 (solder, etc.) for bonding, which is attached to a connection pad of the adherend 16, and pressed while the electrically conductive material is melted, whereby electrical connection between the semiconductor chip 5 and the adherend 16 can be ensured to fix the semiconductor chip 5 to the adherend 16. Since the under-fill material 2 is attached on the circuit surface 3a of the semiconductor chip 5, a space between the semiconductor chip 5 and the adherend is filled with the under-fill material 2 concurrently with electrical connection of the semiconductor chip 5 and the adherend 16.

Generally, in the mounting process, the temperature is 100 to 300° C. as a heating condition, and the pressure is 0.5 to 500 N as a pressing condition. A heat pressure-bonding treatment in the mounting process maybe carried out in a multiple stage. For example, such a procedure can be employed that a treatment is carried out at 150° C. and 100 N for 10 seconds, followed by carrying out a treatment at 300° C. and 100 to 200 N for 10 seconds. By carrying out the heat pressure-bonding treatment in a multiple stage, a resin between the connection member and the pad can be efficiently removed to obtain a better metal-metal joint.

As the adherend 6, a lead frame, various kinds of substrates such as and a circuit substrate (such as a wiring circuit substrate), and other semiconductor elements can be used. Examples of the material of the substrate include, but are not limited to, a ceramic substrate and a plastic substrate. Examples of the plastic substrate include an epoxy substrate, a bismaleimide triazine substrate, a polyimide substrate, and a glass epoxy substrate.

In the mounting process, one or both of the connection member and the electrically conductive material are melted to connect the bump 4 of the connection member forming surface 3a of the semiconductor chip 5, and the electrically conductive material 17 on the surface of the adherend 16, and the temperature at which the bump 4 and the electrically conductive material 17 are melted is normally about 260° C. (for example 250° C. to 300° C.). The sealing sheet according to this embodiment can be made to have such a heat resistance that it can endure a high temperature in the mounting process, by forming the under-fill material 2 from an epoxy resin or the like.

[Under-Fill Material Curing Step]

After performing electrical connection between the semiconductor element 5 and the adherend 16, the under-fill material 2 is cured by heating. Consequently, the surface of the semiconductor element 5 can be protected, and connection reliability between the semiconductor element 5 and the adherend 16 can be ensured. The heating temperature for curing the under-fill material is not particularly limited, and may be about 150 to 250° C. When the under-fill material is cured by a heating treatment in a mounting process, this step can be omitted.

[Sealing Step]

Next, a sealing step may be carried out for protecting the whole of a semiconductor device 20 including the mounted semiconductor chip 5. The sealing step is carried out using a sealing resin. The sealing conditions at this time are not particularly limited, and normally the sealing resin is heat-cured by heating at 175° C. for 60 seconds to 90 seconds, but the present invention is not limited thereto and, for example, the sealing resin may be cured at 165° C. to 185° C. for several minutes.

The sealing resin is not particularly limited as long as it is a resin having an insulating property (insulating resin), and can be selected from sealing materials such as known sealing resins and used, but an insulating resin having elasticity is more preferable. Examples of the sealing resin include a resin composition containing an epoxy resin. Examples of the epoxy resin include the epoxy resins described previously as an example. The sealing resin by the resin composition containing an epoxy resin may contain, as a resin component, a thermosetting resin (phenol resin, etc.), a thermoplastic resin, and so on in addition to an epoxy resin. The phenol resin can also be used as a curing agent for the epoxy resin, and examples of such a phenol resin include the phenol resins described previously as an example.

[Semiconductor Device]

A semiconductor device obtained using the sealing sheet will now be described with reference to the drawings (see FIG. 2H). In the semiconductor device 20 according to this embodiment, the semiconductor element 5 and the adherend 16 are electrically connected through the bump (connection member) 4 formed on the semiconductor element 5 and the electrically conductive material 7 provided on the adherend 16. The under-fill material 2 is placed between the semiconductor element 5 and the adherend 16 so as to fill a space therebetween. The semiconductor device 20 is obtained by the above-mentioned production method employing the predetermined under-fill material and alignment using irradiation of light, and therefore, good electrical connection is realized between the semiconductor element 5 and the adherend 16. Thus, protection of the surface of the semiconductor element 5, filling of a space between the semiconductor element 5 and the adherend 6, and electrical connection between the semiconductor element 5 and the adherend 16 are kept at an adequate level, respectively, so that high reliability can be exhibited as the semiconductor device 20.

### Second Embodiment

A semiconductor wafer with a circuit formed on one surface is used in the first embodiment, whereas in this embodiment, a semiconductor device is produced using a semiconductor wafer with circuits formed on both surfaces. Since the semiconductor wafer used in this embodiment has an intended thickness, a grinding step is omitted. Thus, as a sealing sheet in the second embodiment, a sealing sheet including a dicing tape and a predetermined under-fill material laminated on the dicing tape is used. Typical steps prior to a position matching step in the second embodiment include a providing step of providing the sealing sheet, a bonding step of bonding together a semiconductor wafer, in which circuit surfaces each having a connection member are formed on both surfaces thereof, and the under-fill material of the sealing sheet, a dicing step of dicing the semiconductor wafer to form a semiconductor element with the under-fill material, and a pickup step of peeling off the semiconductor element with the under-fill material from the sealing sheet. Thereafter, the position matching step and the subsequent steps are carried out to produce a semiconductor device.

[Providing Step]

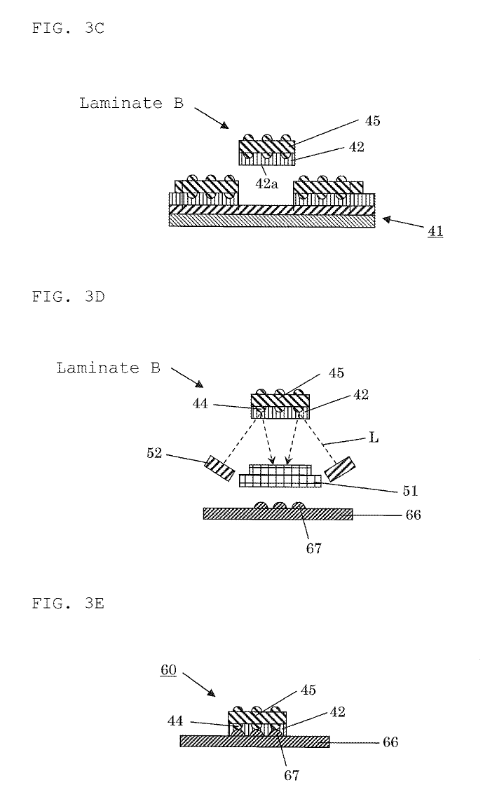

In the providing step, a sealing sheet including a dicing tape 41 and a predetermined under-fill material 42 laminated on the dicing tape 41 is provided (see FIG. 3A). The dicing tape 41 includes a base material 41a and a pressure-sensitive adhesive layer 41b laminated on the base material 41a. The under-fill material 42 is laminated on the pressure-sensitive adhesive layer 41b. The base material 41a and the pressure-sensitive adhesive layer 41b of the dicing tape 41 and the under-fill material 42, which are the same as those in the first embodiment, can be used.

[Bonding Step]

In the bonding step, as shown in FIG. 3A, a semiconductor wafer 43, in which circuit surfaces each having a connection member 44 are formed on both surfaces thereof, and the under-fill material 42 of the sealing sheet are bonded together. Since the strength of a semiconductor wafer thinned to a predetermined thickness is low, the semiconductor wafer may be fixed to a support such as a support glass with a temporary fixing material interposed therebetween for the purpose of reinforcement in some cases (not shown). In this case, a step of peeling off the support together with the temporary fixing material may be included after bonding the semiconductor wafer and the under-fill material together. The circuit surfaces by which the semiconductor wafer 43 is bonded to the under-fill material 42 may be changed according to the intended structure of the semiconductor device.

The semiconductor wafer 43 is the same as the semiconductor wafer in the first embodiment except that circuit surfaces each having the connection member 44 are formed on both surfaces, and the semiconductor wafer 43 has a predetermined thickness. Connection members 44 on both surfaces of the semiconductor wafer 43 may or may not be electrically connected. For electrical connection of connection members 44, mention is made for connection provided through a via called a TSV type. For bonding conditions, the bonding conditions in the first embodiment can be suitably employed.

[Dicing Step]

In the dicing step, the semiconductor wafer 43 and the under-fill material 42 are diced to form a semiconductor element 45 with the under-fill material (see FIG. 3B). For dicing conditions, the conditions in the first embodiment can be suitably employed. Since dicing is conducted on the exposed circuit surface of the semiconductor wafer 43, a dicing position is easily detected, however, dicing may be performed after light is irradiated to confirm the dicing position as necessary.

[Pickup Step]

In the pickup step, the semiconductor element 45 with the under-fill material 42 is peeled off from the dicing tape 41 (FIG. 3C). For pickup conditions, the pickup conditions in the first embodiment can be suitably employed.

In the sealing sheet of this embodiment, the peel strength of the under-fill material from the dicing tape is preferably 0.03 to 0.10 N/20 mm. Accordingly, pickup of the semiconductor element with an under-fill material can be easily performed.

[Position Matching Step]

Next, in the position matching step, as shown in FIG. 3D, light L is irradiated to the exposed surface 42a (see FIG. 3C) of the under-fill material 42 of the semiconductor element 45 with the under-fill material, and a relative position of the semiconductor element 45 and the adherend 66 is matched to a predetermined position for connection to each other. For conditions in the position matching step, the conditions in the first embodiment can be suitably employed.

[Mounting Process]

In the mounting process, the semiconductor element 45 and the adherend 66 are electrically connected through the connection member 44 while filling a space between the adherend 66 and the semiconductor element 45 using the under-fill material 42 (see FIG. 3E). For conditions in the mounting process, the conditions in the first embodiment can be suitably employed. Consequently, a semiconductor device 60 according to this embodiment can be produced.

Subsequently, as in the first embodiment, an under-fill material curing step and a sealing step may be carried out as necessary.

### Third Embodiment

In the first embodiment, a back surface grinding tape is used as a constituent member of a sealing sheet, whereas in this embodiment, a pressure-sensitive adhesive layer of the back surface grinding tape is not provided, and a base material alone is used. Thus, a sealing sheet of this embodiment is in such a state that an under-fill material is laminated on a base material. In this embodiment, a grinding step can be optionally carried out, but irradiation of ultraviolet rays before a pickup step is not carried out because a pressure-sensitive adhesive layer is omitted. Except for these aspects, a predetermined semiconductor device can be produced through the same steps as those in the first embodiment.

### Other Embodiments

In the first to third embodiments, dicing using a dicing blade is employed in the dicing step, but in place thereof, so-called stealth dicing may be employed in which a reformed part is formed in a semiconductor wafer by laser irradiation, and the semiconductor wafer is divided along the reformed part to be fragmented.

### EXAMPLES

Preferred Examples of the present invention will be illustratively described in detail below. However, for the materials, the blending amounts, and so on described in Examples, the scope of the present invention is not intended to be limited thereto unless definitely specified. The part(s) means “part(s) by weight”.

### Examples 1 to 5 and Comparative Examples 1 and 2

(Preparation of Sealing Sheet)

The following components were dissolved in methyl ethyl ketone at a ratio shown in Table 1 to prepare an adhesive composition solution having a solid concentration of 23.6 to 60.6% by weight.

Elastomer 1: acrylic acid ester-based polymer having a butyl acrylate-acrylonitrile as a main component (trade name “SG-28GM” manufactured by Nagase chemteX Corporation)

Elastomer 2: acrylic acid ester-based polymer having an ethyl acrylate-methyl methacrylate as a main component (trade name “Paraclone W-197CM” manufactured by Negami Chemical Industrial Co., Ltd.)

Epoxy resin 1: trade name “Epicoat 828” manufactured by JER Corporation

Epoxy resin 2: trade name “Epicoat 1004” manufactured by JER Corporation

Phenol resin: trade name “Mirex XLC-4L” manufactured by Mitsui Chemicals, Incorporated

Filler 1: spherical silica (trade name “YC100C-MLC” manufactured by Admatechs)

Filler 2: spherical silica (trade name “SO-25R” manufactured by Admatechs)

Organic acid: o-anisic acid (trade name “Orthoanisic Acid” manufactured by Tokyo Chemical Industry Co., Ltd.)

Curing agent: Imidazole catalyst (trade name “2PHZ-PW” manufactured by Shikoku Chemicals Corporation)

The adhesive composition solution was applied onto a release-treated film made of a silicone release-treated polyethylene terephthalate film having a thickness of 50 μm as a release liner (separator), and thereafter dried at 130° C. for 2 minutes to thereby prepare an under-fill material having a thickness of 45 μm.

The under-fill material was bonded onto a pressure-sensitive adhesive layer of a back grind tape (trade name “UB-2154” manufactured by Nitta Denko Corporation) using a hand roller to prepare a sealing sheet.

(Measurement of Haze)

The haze of the under-fill material was measured using Haze Meter HM-150 (manufactured by MURAKAMI COLOR RESEARCH LABORATORY CO., Ltd.; product No.: HM-150). The measurement was performed in accordance with JIS K 7136. The results are shown in Table 1.

(Measurement of Thermal Expansion Coefficient α)

A thermal expansion coefficient α was measured using a thermomechanical measurement apparatus (Model: Q-400EM manufactured by TA Instruments). Specifically, a sample was made to have a size of 15 mm (length)×5 mm (width)×200 μm (thickness), the measurement sample was set in a tool for film tensile measurement in the apparatus, and then placed under conditions of tensile load: 2 g and temperature rising rate: 10° C./min in a temperature zone from −50 to 300° C., and a thermal expansion coefficient α was calculated from expansion rate at 20° C. to 60° C. The results are shown in Table 1.

(Measurement of Storage Elastic Modulus E′)

First the prepared under-fill material was subjected to a heat-curing treatment at 175° C. for an hour, and then a storage elastic modulus was measured using a solid viscoelasticity measurement apparatus (Model: RSA III manufactured by Rheometric Scientific Co., Ltd.). Specifically, a sample was made to have a size of 40 mm (length)×10 mm (width)×200 μm (thickness), the measurement sample was set in a tool for film tensile measurement, a tensile storage elastic modulus, and loss elastic modulus in a temperature zone of from −50 to 300° C. were measured under conditions of frequency of 1 Hz and temperature rising rate of 10° C./min, and a storage elastic modulus (E′) at 25° C. was read. The results are shown in Table 1.

(Measurement of Glass Transition Temperature)

The method for measuring a glass transition temperature of an under-fill material is as follows. An under-fill material was first heat-cured by a heating treatment at 175° C. for an hour, and then cutout using a cutter knife into a strip having a thickness of 200 μm, a length of 40 mm (measurement length) and width of 10 mm, and a storage elastic modulus and a loss elastic modulus at −50 to 300° C. were measured using a solid viscoelasticity measurement apparatus (RSA III manufactured by Rheometric Scientific Co., Ltd.). For measurement conditions, the frequency was 1 Hz and the temperature rising rate was 10° C./min. Further, a value of tan δ (G″ (loss elastic modulus)/G′ (storage elastic modulus)) was calculated to thereby obtain a glass transition temperature. The results are shown in table 1.

(Measurement of Rupture Elongation)

Using a roll laminator (device name “MRK-600” manufactured by MCK CO., LTD.), an under-fill material prepared at 70° C. and 0.2 MPa was laminated to obtain a 120 μm-thick under-fill material for measurement. The under-fill material for measurement was cut to a size of 10 mm (width)×30 mm (length) to obtain a test piece, a tension test was conducted at a tension rate of 50 mm/min, a chuck-to-chuck distance of 10 mm, and a temperature of 25° C. using “AUTOGRAPH ASG-50D Model” (manufactured by Shimadzu Corporation) as a tension tester. A ratio of a chuck-to-chuck distance, at the time when the test piece was ruptured, to the chuck-to-chuck distance before the test was determined, and defined as a rupture elongation (%).

(Preparation of Semiconductor Device)

A silicon wafer with bumps on one surface, in which bumps were formed on one surface, was provided, and the prepared sealing sheet was bonded to a surface on which the bumps of the silicon wafer with bumps on one surface were formed with the under-fill material as a bonding surface. As the silicon wafer with bumps on one surface, the following article was used. Bonding conditions were as follows. The ratio of the thickness Y (=45 μm) of the under-fill material to the height X (=45 μm) of a connection member (Y/X) was 1. In four corners of a region (7.3 mm×7.3 mm) to be cut out as a semiconductor element, alignment marks were given at a distance of 0.15 mm from each side.

<Silicon Wafer with Bumps on One Surface>

Diameter of silicon wafer: 8 inches

Thickness of silicon wafer: 0.7 mm (700 μm)

Height of bump: 45 μm

Pitch of bump: 50 μm

Material of bump: solder

<Bonding Conditions>

Bonding device: trade name “DSA 840-WS” manufactured by NITTO SEIKI CO., Ltd.

Bonding speed: 5 mm/min

Bonding pressure: 0.25 MPa

Stage temperature at the time of bonding: 80° C.

Degree of vacuum at the time of bonding: 150 Pa

A silicon wafer with bumps on one surface and a sealing sheet were bonded together in accordance with the procedure described above, followed by grinding the back surface of the silicon wafer under the following conditions.

<Grinding Conditions>

Grinding apparatus: trade name “DFG-8560” manufactured by DISCO Corporation

Semiconductor wafer: back surface ground from a thickness of 0.7 mm (700 μm) to 0.2 mm (200 μm)

After the back surface was ground, a silicon wafer was peeled off with an under-fill material from a back grind tape together, and the silicon wafer was bonded onto a pressure-sensitive adhesive layer of a dicing tape (DU-300 manufactured by Nitto Denko Corporation) and thereby fixed. At this time, the back surface of the silicon wafer and the pressure-sensitive adhesive layer were bonded together, and the under-fill material bonded to the circuit surface of the silicon wafer was exposed. Light was irradiated to the exposed surface of the under-fill material to determine a dicing position.

Next, according to the determined dicing position, dicing of the semiconductor wafer was performed under the following conditions. Dicing was performed by full cut so as to have a chip size of 7.3 mm×7.3 mm.

<Dicing Conditions>

Dicing device: trade name “DFD-6361” manufactured by DISCO Corporation

Dicing ring: “2-8-1” (manufactured by DISCO Corporation)

Dicing speed: 30 mm/sec

Dicing blade:

Z1; “2030-SE 27HCDD” manufactured by DISCO Corporation

Z2; “2030-SE 27HCBB” manufactured by DISCO Corporation

Dicing blade rotation number:

Z1; 40,000 rpm

Z2; 45,000 rpm

Cut mode: step cut

Wafer chip size: 7.3 mm×7.3 mm

Next, a laminate of the under-fill material and the semiconductor chip with bumps on one surface was picked up by a method of push-up with a needle from the base material side of the sealing sheet. The pickup conditions were as follows.

<Pickup Conditions>

Pickup device: trade name “SPA-300” manufactured by SHINKAWA LTD.

The number of needles: 9

Needle push-up amount: 500 μm (0.5 mm)

Needle push-up speed: 20 mm/second

Pickup time: 1 second

Expanding amount: 3 mm

The exposed surface of the under-fill material was subjected to position matching by irradiation of light, and finally the semiconductor chip was heat pressure-bonded to the BGA substrate to perform mounting of the semiconductor chip with the bump-formed surface of the semiconductor chip and the BGA substrate facing each other under the heat pressure-bonding conditions described below. In this way, a semiconductor device with a semiconductor chip mounted on a BGA substrate was obtained. In this step, a two-stage treatment was performed in which heat pressure-bonding was carried out under the heat pressure-bonding condition 2 subsequently to the heat pressure-bonding condition 1.

<Heat Pressure-Bonding Condition 1>

Pickup device: trade name “FCB-3” manufactured by Panasonic Corporation

Heating temperature: 150° C.

Load: 98 N

Retention time: 10 seconds

<Heat Pressure-Bonding Condition 2>

Pickup device: trade name “FCB-3” manufactured by Panasonic Corporation

Heating temperature: 260° C.

Load: 98 N

Retention time: 10 seconds

(Evaluation of Position Matching by Observation of Solder Joint)

10 samples were prepared for each of the semiconductor devices of the examples and comparative examples, and the semiconductor device was embedded in an embedding epoxy resin. The semiconductor device was then cut in a direction perpendicular to the substrate in such a manner that the solder joint was exposed, and the cross section of the exposed solder joint was polished. Thereafter, the polished cross section of solder joint was observed with an optical microscope (magnification: 1,000). The semiconductor device was rated “◯” when the solder joint was joined, and the semiconductor device was rated “×” when the solder joint was got out of position and was not joined with the pad on the substrate side in even one sample. The results are shown in Table 1.

(Evaluation of Reliability of Semiconductor Device)

10 samples were prepared for each of the semiconductor devices of the examples and comparative examples, a heat cycle with the temperature rising from −55° C. to 125° C. for 30 minutes in one cycle was repeated 500 times, and the semiconductor device was then embedded in an embedding epoxy resin. The semiconductor device was then cut in a direction perpendicular to the substrate in such a manner that the solder joint was exposed, and the cross section of the exposed solder joint was polished. Thereafter, the polished cross section of solder joint was observed with an optical microscope (magnification: 1,000). The semiconductor device was rated “∘” when the solder joint was not ruptured, and the semiconductor device was rated “×” when the solder joint was ruptured in even one sample. The results are shown in Table 1.

TABLE 1

| | | | | | Comparative | Comparative |
|---|---|---|---|---|---|---|
| | | Example 1 | Example 2 | Example 3 | Example 1 | Example 2 |
| Composition | Elastomer 1 | — | — | 4.8 | 7.8 | — |
| | Elastomer 2 | 9.2 | 10.8 | — | — | 20 |
| | Epoxy resin 1 | 15 | 15 | 4 | 16 | 6.5 |
| | Epoxy resin 2 | 5 | 5 | 16 | 4 | 16.5 |
| | Phenol resin | 23.4 | 23.4 | 23.4 | 23.4 | 22 |
| | Filler 1 | 67.6 | 72 | — | — | 10 |
| | Filler 2 | — | — | 5.6 | 126 | — |
| | Organic acid | 2.6 | 2.6 | 2.6 | 2.6 | 2.6 |
| | Curing agent | 0.15 | 0.15 | 0.15 | 0.15 | 0.15 |
| Evaluation | Haze [%] | 9.2 | 25 | 66 | 98 | 13 |
| | Thermal expansion coefficient α [ppm/K] | 48 | 37 | 83 | 15 | 93 |
| | Storage elastic modulus E′ [MPa] | 1,270 | 3,200 | 2,800 | 8,200 | 2,750 |
| | Tg [° C.] | 128 | 122 | 148 | 136 | 135 |
| | α × E′ [Pa/K] | 60,960 | 118,400 | 232,400 | 123,000 | 255,750 |
| | Rupture elongation [%] | 155 | 130 | 490 | 8 | 880 |
| | Junction evaluation results | ◯ | ◯ | ◯ | X | ◯ |
| | Reliability test, number of | 10/10 | 10/10 | 10/10 | — | 5/10 |
| | non-defective products | | | | | |
| | Assessment | ◯ | ◯ | ◯ | X | X |

In the table, the unit of the value of each component is parts by weight.

As is apparent from Table 1, the solder joint did not get out of position, and occurrence of rupture of the solder joint was suppressed in the semiconductor devices of the examples. On the other hand, in Comparative Example 1, the solder joint got out of position because the haze of the under-fill material was too high to perform position matching for solder junction, and accordingly it was not able to perform evaluation of the reliability of the semiconductor device. In Comparative Example 2, the value of α×E′ of the under-fill material exceeded the specified range so that it was not able to reduce a thermal response behavior between the semiconductor chip and the BGA substrate, and thus rupture occurred in the solder joint.

### REFERENCE CHARACTERS LIST

1 Backside grinding tape

1a, 11a Base material

1b, 11b Pressure-sensitive adhesive layer

2, 42 Under-fill material

2a, 42a Exposed surface of under-fill material

3, 43 Semiconductor wafer

3a, 43a Circuit surface of semiconductor wafer

3b Surface of semiconductor wafer on a side opposite to circuit surface

4, 44 Bump (connection member)

5, 45 Semiconductor chip (semiconductor element)

6, 66 Adherend

7, 67 Conducting material

10 Sealing sheet

11, 41 Dicing tape

20, 60 Semiconductor device

31a, 31b Imaging device

32a, 32b Illuminator

L Light

1. An under-fill material, having:
a haze of 70% or less before a heat curing treatment; and
a storage elastic modulus E′ [MPa] and a thermal expansion coefficient α [ppm/K] after the under-fill material is subjected to a heat curing treatment at 175° C. for 1 hour that satisfy the following formula (1) at 25° C.:
10000<E′×α<250000 [Pa/K] (1).

2. The under-fill material according to claim 1, having:
a range of not more than 20000 Pa·s as a viscosity at 40 to 100° C.; and
a minimum viscosity of 100 Pa·s or more at 100 to 200° C.

3. A sealing sheet which comprises a pressure-sensitive adhesive tape including a base material and a pressure-sensitive adhesive layer provided on the base material; and
the under-fill material according to claim 1 laminated on the pressure-sensitive adhesive layer.

4. The sealing sheet according to claim 3, wherein a peel strength of the under-fill material from the pressure-sensitive adhesive tape is 0.03 to 0.10 N/20 mm.

5. The sealing sheet according to claim 3, wherein a rupture elongation of the under-fill material at 25° C. is not less than 10% and not more than 800%.

6. The sealing sheet according to claim 3, wherein the pressure-sensitive adhesive tape is a backside grinding tape or a dicing tape for a semiconductor wafer.

7. A method for producing a semiconductor device which comprises an adherend, a semiconductor element electrically connected to the adherend, and an under-fill material filling a space between the adherend and the semiconductor element, the method comprising the steps of:
providing a semiconductor element with an under-fill material in which the under-fill material according to claim 1 is bonded to the semiconductor element; and
electrically connecting the semiconductor element and the adherend to each other while filling the space between the adherend and the semiconductor element with the under-fill material.
